(19) United States
(12) Patent Application Publication
(10) Pub. No.: US 2025/0268072 A1
(43) Pub. Date: Aug. 21, 2025

(54) DISPLAY PANEL AND DISPLAY DEVICE INCLUDING THE SAME

(71) Applicant: Samsung Display Co., Ltd., Yongin-si (KR)

(72) Inventors: JAE-HOON KIM, Yongin-si (KR); JEEHOON PARK, Yongin-si (KR)

(73) Assignee: Samsung Display Co., Ltd., Yongin-si (KR)

(21) Appl. No.: 19/045,760

(22) Filed: Feb. 5, 2025

(30) Foreign Application Priority Data
Feb. 19, 2024 (KR) 10-2024-0023722

(51) Int. Cl. H10K 59/80; H10K 59/38

(52) U.S. Cl. CPC H10K 59/873; H10K 59/38

(57) ABSTRACT

Provided is a display device including a display panel, and a window disposed on the display panel, wherein the display panel includes a base layer, a circuit layer disposed on the base layer, a display element layer disposed on the circuit layer and including a light-emitting element, and an encapsulation layer disposed on the display element layer, and the encapsulation layer includes a first inorganic layer disposed on the display element layer, an organic layer disposed on the first inorganic layer, and a second inorganic layer disposed on the organic layer. The organic layer includes a resin material and an acidic material and provides protons to the light-emitting element.

### CROSS-REFERENCE TO RELATED APPLICATION(S)

This application claims priority to and benefits of Korean Patent Application No. 10-2024-0023722 under 35 U.S.C. § 119, filed on Feb. 19, 2024, the entire contents of which are incorporated herein by reference.

### BACKGROUND

Embodiments relate to a display panel and a display device including the display panel, and more particularly, to a display panel with enhanced light-emitting properties and improved reliability and a display device including the display panel.

Various display devices used for multimedia devices such as a television, a mobile phone, a tablet computer, a navigation system, and a game console are being developed. In the display devices, a so-called self-luminous display element, which realize display by causing a light-emitting material including an organic compound to emit light, is being used.

In order to improve the color gamut of a display device, development of a light-emitting element using quantum dots as a light-emitting material is underway, and it is required to improve the lifespan and emission efficiency of the light-emitting element using quantum dots.

### SUMMARY

Embodiments provide a display panel with improved light-emitting properties and the color gamut.

Embodiments also provide a display device including a display panel with improved reliability.

In an embodiment, a display device may include: a display panel; and a window disposed on the display panel, wherein the display panel includes a base layer, a circuit layer disposed on the base layer, a display element layer disposed on the circuit layer and including a light-emitting element, and an encapsulation layer disposed on the display element layer, and the encapsulation layer includes a first inorganic layer disposed on the display element layer, an organic layer disposed on the first inorganic layer, and a second inorganic layer disposed on the organic layer, the organic layer may include a resin material and an acidic material and may provide protons to the light-emitting element.

In an embodiment, the protons may be generated from the acidic material.

In an embodiment, a material included in the window may be different from each of the resin material and the acidic material.

In an embodiment, the acidic material may have a pKₐ of about 3.0 to about 3.5.

In an embodiment, the acidic material may have a molecular weight of about 180 to about 200.

In an embodiment, the acidic material may include citric acid.

In an embodiment, the resin material may include an acrylate-based compound or an epoxy-based compound.

In an embodiment, the organic layer further may include an acid polymer material.

In an embodiment, the acid polymer material may include polyacrylic acid (PAA).

In an embodiment, the light-emitting element may include: a first electrode; a hole transport region disposed on the first electrode; a light-emitting layer disposed on the hole transport region; an electron transport region disposed on the light-emitting layer; and a second electrode disposed on the electron transport region, and the light-emitting layer may include quantum dots.

In an embodiment, the electron transport region may include a metal oxide.

In an embodiment, the display device may further include an optical layer disposed below the window.

In an embodiment, the light-emitting element may include a first light-emitting element overlapping a first light-emitting region, a second light-emitting element overlapping a second light-emitting region, and a third light-emitting element overlapping a third light-emitting region, and the optical layer may include a first optical part overlapping the first light-emitting region, a second optical part overlapping the second light-emitting region, and a third optical part overlapping the third light-emitting region.

In an embodiment, the first optical part, the second optical part, and the third optical part may each include a polymer photosensitive resin.

In an embodiment, the first optical part may include a red colorant, the second optical part may include a green colorant, and the third optical part may include a blue colorant.

In an embodiment, the second optical part, and the third optical part may each include a color film.

In an embodiment, the optical layer may further include an adhesive layer disposed below the first optical part, the second optical part, and the third optical part.

In an embodiment, at least one among the first optical part, the second optical part, and the third optical part may include a polymeric photosensitive resin, and remains among the first optical part, the second optical part, and the third optical part may include a color film.

In an embodiment, a display panel includes: a base layer; a circuit layer disposed on the base layer; a display element layer disposed on the circuit layer and including a light-emitting element; and an encapsulation layer disposed on the display element layer, wherein the encapsulation layer includes a first inorganic layer disposed on the display element layer, an organic layer disposed on the first inorganic layer and including citric acid, and a second inorganic layer disposed on the organic layer.

In an embodiment, an electronic device which provides an image, may include a display device a power supply module for supplying power to the display device, the display device including: a display panel; and a window disposed on the display panel, wherein the display panel may include: a base layer, a circuit layer disposed on the base layer, a display element layer disposed on the circuit layer and comprising a light-emitting element, and an encapsulation layer disposed on the display element layer, the encapsulation layer may include: a first inorganic layer disposed on the display element layer, an organic layer disposed on the first inorganic layer, and a second inorganic layer disposed on the organic layer, and the organic layer comprises a resin material and an acidic material and provides protons to the light-emitting element.

### BRIEF DESCRIPTION OF THE DRAWINGS

The accompanying drawings are included to provide a further understanding of the disclosure, and are incorporated in and constitute a part of the description. The drawings illustrate embodiments and, together with the description, serve to explain principles of the disclosure. In the drawings:

FIG. 1 is a block diagram of an electronic device according to an embodiment of the inventive concept.

FIG. 2 is a schematic perspective view illustrating a display device according to an embodiment;

FIG. 3 is a schematic cross-sectional view of a display device according to an embodiment;

FIG. 4 is an enlarged schematic plan view illustrating a part of a display device according to an embodiment;

FIG. 5 is a schematic cross-sectional view of a display device according to an embodiment;

FIG. 6 is a schematic cross-sectional view of a light-emitting element included in a display device according to an embodiment;

FIG. 7 is a schematic cross-sectional view of a quantum dot included in a display device according to an embodiment; and

FIGS. 8A, 8B, and 8C are respectively schematic cross-sectional views of a display device according to other embodiments.

### DETAILED DESCRIPTION OF THE EMBODIMENTS

Hereinafter, embodiments will be described with reference to the accompanying drawings.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. Also, in the drawings, the thicknesses, the ratios, and the dimensions of the elements are exaggerated for effective description of the technical contents. The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the disclosure. The singular forms include the plural forms as well, unless the context clearly indicates otherwise.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

It will be understood that the term “includes” or “comprises”, when used in the description, specifies the presence of stated features, integers, steps, operations, elements, components, or a combination thereof, but does not preclude the presence or addition of one or more other features, integers, steps, operations, elements, components, or combinations thereof.

In the description, it will be understood that “being directly disposed” means that there are no intervening layers, films, regions, plates, or the like between a portion of layers, films, regions, plates, or the like and another portion. For example, “being directly disposed” may mean to be disposed between two layers or two members without using an additional member such as an adhesive member or like.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device according to an embodiment will be described with reference to the accompanying drawings.

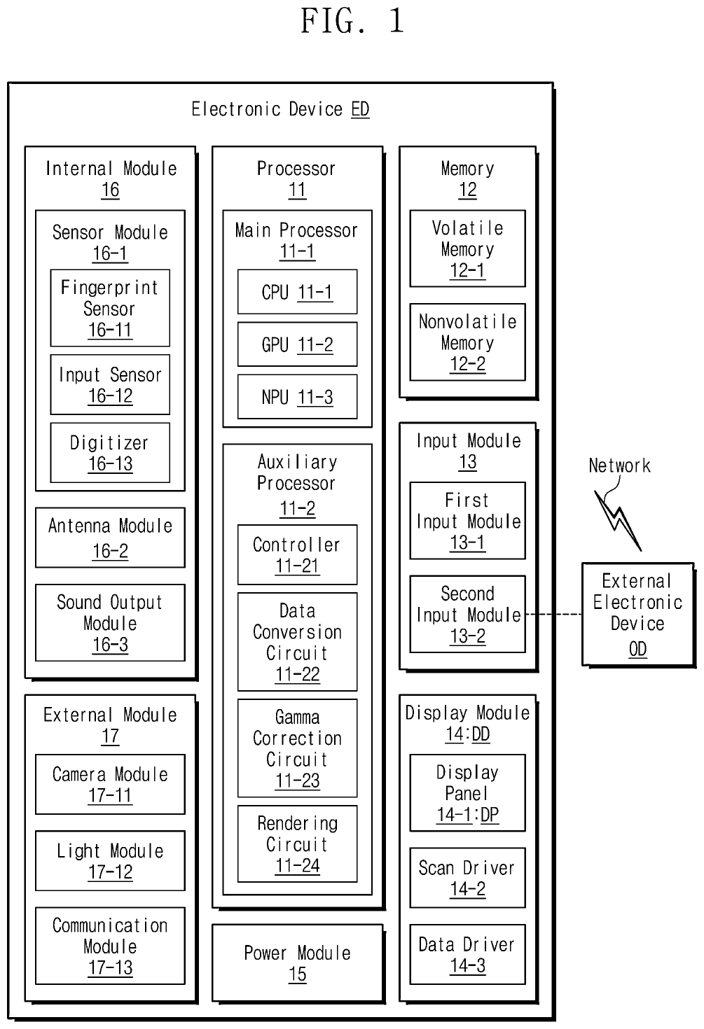

FIG. 1 is a block diagram of an electronic device according to an embodiment of the inventive concept.

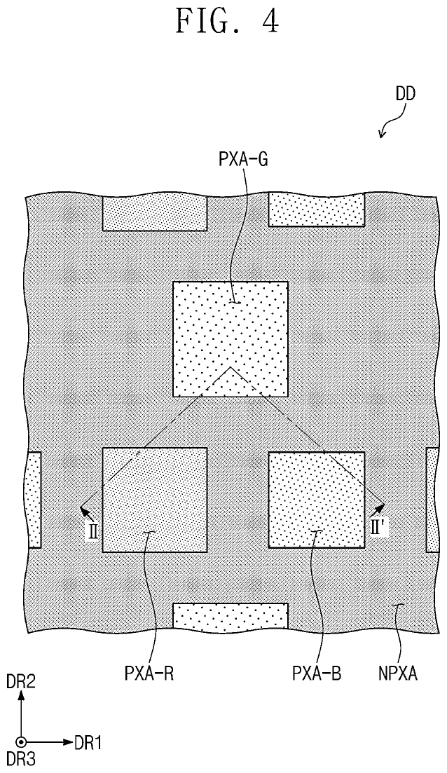

Referring to FIG. 1, an electronic device ED may output various information through a display module 14 in an operating system. In case that a processor 11 executes an application stored in a memory 12, the display module 14 provides application information to a user through a display panel 14-1. Meanwhile, the display panel 14-1 may refer to the display panel DP (see FIG. 3).

The processor 11 may obtain an external input through an input module 13 or a sensor module 16-1 and may execute an application corresponding to the external input. For example, when a user selects a camera icon displayed on the display panel 14-1, the processor 11 may obtain a user's input through an input sensor 16-12 and may activate a camera module 17-1. The processor 11 may transmit, to the display module 14, image data corresponding to a captured image that is obtained through the camera module 17-1. The display module 14 may display an image corresponding to the captured image through the display panel 14-1.

For another example, in case that personal information authentication is executed in the display module 14, a fingerprint sensor 16-11 may obtain input fingerprint information as input data. The processor 11 may compare the input data obtained through the fingerprint sensor 16-11 with authentication data stored in the memory 12 and may execute an application according to a comparison result. The display module 14 may display information that is executed according to a logic of the application through the display panel 14-1.

For another example, in case that a music streaming icon displayed through the display module 14 is selected, the processor 11 may obtain a user input through the input sensor 16-12 and may activate a music streaming application stored in the memory 12. In case that a music execution command is input in the music streaming application, the processor 11 may activate a sound output module 16-3 and may provide sound information corresponding to the music execution command to a user.

An operation of the electronic device ED is briefly described above. Hereinafter, a configuration of the electronic device ED will be described in detail. Some of components of the electronic device ED to be described later may be integrated and provided as one component, and one component may be separated and provided as two or more components.

For example, the electronic device ED may communicate with an external electronic device OD through a network (for example, short-range wireless communication network or long-range wireless communication network). According to an embodiment, the electronic device ED may include the processor 11, the memory 12, the input module 13, the display module 14, a power module 15, an internal module 16, and an external module 17. According to an embodiment, in the electronic device ED, at least one of the components described above may be omitted, or one or more other components may be added. According to an embodiment, some (for example, the sensor module 16-1, an antenna module 16-2, or the sound output module 16-3) of the components described above may be integrated with another component (for example, the display module 14).

The processor 11 may execute software to control at least one other component (for example, hardware or software component) of the electronic device ED connected to the processor 11 and perform various data processing or operations. According to an embodiment, as at least part of the data processing or operations, the processor 11 may store data or a command received from another component (for example, the input module 13, the sensor module 16-1, or a communication module 17-3) in a volatile memory 12-1 and process the data or command stored in the volatile memory 12-1, and result data may be stored in a nonvolatile memory 12-2.

The processor 11 may include a main processor 11-1 and an auxiliary processor 11-2. The main processor 11-1 may include one or more among a central processing unit (CPU) 11-11 and an application processor (AP). The main processor 11-1 may further include one or more among a graphic processing unit (GPU) 11-12, a communication processor (CP), and an image signal processor (ISP). The main processor 11-1 may further include a neural processing unit (NPU) 11-13. A neural processing unit may be a processor that is specialized for processing an artificial intelligence model, and the artificial intelligence model may be generated through machine learning. The artificial intelligence model may include artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, and a combination of two or more thereof, but is not limited to the examples described above. The artificial intelligence model may include software structure in addition to or instead of hardware structure. At least two among the processing units and processors described above may be implemented as one integrated component (for example, a single chip) or may be each implemented as an independent component (for example, a plurality of chips).

The auxiliary processor 11-2 may include a controller 11-21. The controller 11-21 may include an interface conversion circuit and a timing control circuit. The controller 11-21 may receive an image signal from the main processor 11-1, may convert data format of the image signal to comply with specifications of interface with the display module 14, and may output image data. The controller 11-21 may output various control signals required for driving the display module 14.

The auxiliary processor 11-2 may further include a data conversion circuit 11-22, a gamma correction circuit 11-23, a rendering circuit 11-24, etc. The data conversion circuit 11-22 may receive image data from the controller 11-21, and may compensate for the image data such that an image may be displayed at a desired luminance according to characteristics of the electronic device ED, a user's setting, or the like, or may convert the image data to reduce power consumption, to compensate for an afterimage, or the like. The gamma correction circuit 11-23 may convert image data, a gamma reference voltage, or the like such that an image displayed on the electronic device ED may have a desired gamma characteristic. The rendering circuit 11-24 may receive image data from the controller 11-21 and render the image data in consideration of pixel arrangement of the display panel 14-1 applied to the electronic device ED, etc. At least one of the data conversion circuit 11-22, the gamma correction circuit 11-23, or the rendering circuit 11-24 may be integrated with another component (for example, the main processor 11-1 or the controller 11-21). At least one of the data conversion circuit 11-22, the gamma correction circuit 11-23, or the rendering circuit 11-24 may be integrated with a data driver 143 to be described later.

The memory 12 may store various pieces of data that are used by at least one component (for example, the processor 11 or the sensor module 16-1) of the electronic device ED, and output data or input data about a command related thereto. The memory 12 may include at least one of the volatile memory 12-1 or the nonvolatile memory 12-2.

The input module 13 may receive data or a command to be used for a component (for example, the processor 11, the sensor module 16-1, or the sound output module 16-3) of the electronic device ED from the outside (for example, a user or the external electronic device OD) of the electronic device ED.

The input module 13 may include a first input module 13-1 to which a command or data is input from a user and a second input module 13-2 to which a command or data is input from the external electronic device OD. The first input module 13-1 may include a microphone, a mouse, a keyboard, a key (for example, a button), or a pen (for example, a passive pen or an active pen). The second input module 13-2 may support a designated protocol for connection to the external electronic device OD wirelessly or by wire. According to an embodiment, the second input module 13-2 may include a high definition multimedia interface (HDMI), a universal serial bus (USB) interface, an SD card interface, or an audio interface. The second input module 13-2 may include a connector, for example, an HDMI connector, a USB connector, an SD card connector, or an audio connector (for example, a headphone connector), for physical connection to the external electronic device OD.

The display module 14 may visually provide information to a user. The display module 14 may include the display panel 14-1, a scan driver 14-2, and the data driver 143. The display module 14 may further include a chassis and a bracket for protecting the display panel 14-1.

The display panel 14-1 may include a liquid crystal display panel, an organic light-emitting display panel, or an inorganic light-emitting display panel, and a type of the display panel 14-1 is not particularly limited. The display panel 14-1 may be a rigid-type or flexible-type panel capable of being rolled or folded. The display module 14 may further include a supporter that supports the display panel 14-1, a bracket, a heat dissipation member, or the like. The display panel 14-1 will be described in detail below with reference to FIG. 3 and subsequent drawings.

The scan driver 14-2 may be mounted on the display panel 14-1 as a driving chip. For example, the scan driver 14-2 may be integrated with the display panel 14-1. For example, the scan driver 14-2 may include an amorphous silicon TFT gate driver circuit (ASG), a low temperature polycrystalline silicon (LTPS) TFT gate driver circuit, or an oxide semiconductor TFT gate driver circuit (OSG) built in the display panel 14-1. The scan driver 14-2 may receive a control signal from the controller 11-21 and output scan signals to the display panel 14-1 in response to the control signal.

The display panel 14-1 may further include a light emission driver. The light emission driver may output a light emission control signal to the display panel 14-1 in response to a control signal received from the controller 11-21. The light emission driver may be formed separately from the scan driver 14-2 or may be integrated with the scan driver 14-2.

The data driver 143 may receive a control signal from the controller 11-21, convert image data into an analog voltage (for example, a data voltage) in response to the control signal, and then outputs data voltages to the display panel 14-1.

The data driver 143 may be integrated with another component (for example, the controller 11-21). Functions of the interface conversion circuit and the timing control circuit of the controller 11-21 described above may be integrated with the data driver 143.

The display module 14 may further include a light emission driver, a voltage generation circuit, and the like. The voltage generation circuit may output various voltages required for driving the display panel 14-1.

The power module 15 may supply power to a component of the electronic device ED. The power module 15 may include a battery that charges a power voltage. The battery may include a non-rechargeable primary cell, a rechargeable secondary cell, or a fuel cell. The power module 15 may include a power management integrated circuit (PMIC). The PMIC may supply optimized power to each of the module described above and a module to be described later. The power module 15 may include a wireless power transmission/reception member electrically connected to the battery. The wireless power transmission/reception member may include a plurality of antenna radiators in a coil form.

The electronic device ED may further include the internal module 16 and the external module 17. The internal module 16 may include the sensor module 16-1, the antenna module 16-2, and the sound output module 16-3. The external module 17 may include the camera module 17-1, a light module 17-2, and the communication module 17-3.

The sensor module 16-1 may sense an input from a user's body or an input from a pen of the first input module 13-1 and generate a data value or an electrical signal corresponding to the input. The sensor module 16-1 may include at least one of the fingerprint sensor 16-11, the input sensor 16-12, or a digitizer 16-13.

The fingerprint sensor 16-11 may generate a data value corresponding to a user's fingerprint. The fingerprint sensor 16-11 may include any one of an optical fingerprint sensor and a capacitive fingerprint sensor.

The input sensor 16-12 may generate a data value corresponding to coordinate information about an input from a user's body or an input from a pen. The input sensor 16-12 may generate the amount of a change in capacitance due to an input as a data value. The input sensor 16-12 may sense an input from a passive pen or transmit/receive data to/from an active pen.

The input sensor 16-12 may measure a bio-signal such as blood pressure, water, or body fat. For example, when a user is in contact with a sensor layer or a sensing panel with a part of the user's body and does not move for a certain amount of time, the input sensor 16-12 may sense a bio-signal on the basis of a change in electric field due to the part of the user's body and output information desired by the user to the display module 14.

The digitizer 16-13 may generate a data value corresponding to coordinate information about an input from a pen. The digitizer 16-13 may generate the amount of an electromagnetic change due to an input as a data value. The digitizer 16-13 may sense an input from a passive pen or transmit/receive data to/from an active pen.

At least one of the fingerprint sensor 16-11, the input sensor 16-12, or the digitizer 16-13 may be implemented as an input sensing layer that is formed on the display panel 14-1 through a continuous process. The fingerprint sensor 16-11, the input sensor 16-12, and the digitizer 16-13 may be disposed above the display panel 14-1, and any one of the fingerprint sensor 16-11, the input sensor 16-12, and the digitizer 16-13, for example, the digitizer 16-13 may be disposed below the display panel 14-1.

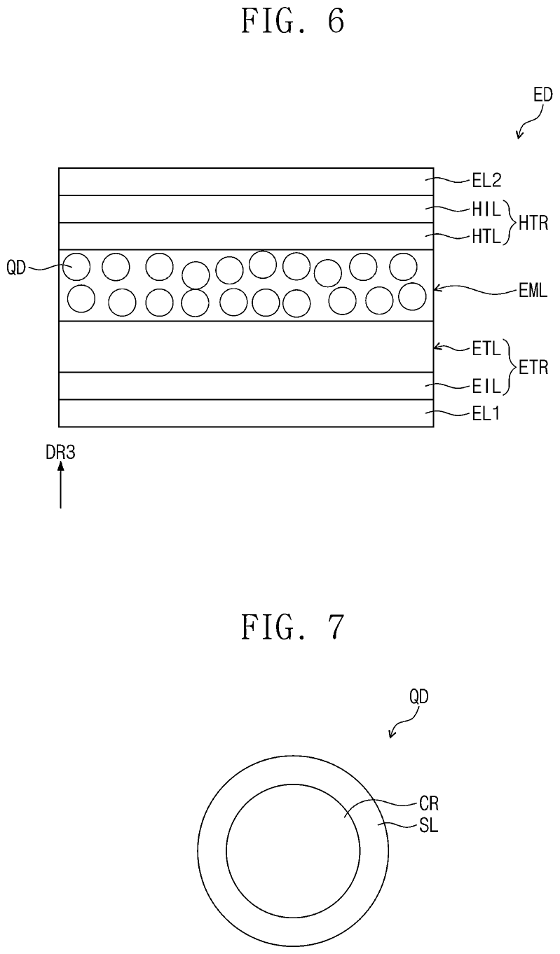

At least two of the fingerprint sensor 16-11, the input sensor 16-12, and the digitizer 16-13 may be formed to be integrated as one sensing panel through the same process. In a case in which the at least two thereof are integrated with one sensing panel, the sensing panel may be disposed between the display panel 14-1 and the window module WM (see FIG. 5) disposed above the display panel 14-1. According to an embodiment, the sensing panel may be disposed on the window module WM (see FIG. 5), and a position of the sensing panel is not particularly limited. FIG. 5 to be described later illustrates an input sensing part ISP disposed between the display panel 14-1 and the window module WM (see FIG. 5) disposed above the display panel 14-1, but an embodiment is not limited thereto.

At least one of the fingerprint sensor 16-11, the input sensor 16-12, or the digitizer 16-13 may be built in the display panel 14-1. For example, at least one of the fingerprint sensor 16-11, the input sensor 16-12, or the digitizer 16-13 may be simultaneously formed through a process of forming elements (for example, a light-emitting element, a transistor, etc.) included in the display panel 14-1.

For example, the sensor module 16-1 may generate a data value or an electrical signal corresponding to an internal state or an external state of the electronic device ED. The sensor module 16-1 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 16-2 may include one or more antennas for transmitting or receiving a signal or power to or from the outside. According to an embodiment, the communication module 17-3 may transmit or receive a signal to or from an external electronic device through an antenna suitable for a communication method. An antenna pattern of the antenna module 16-2 may be integrated with one component (for example, the display panel 14-1) of the display module 14, the input sensor 16-12, or the like.

The sound output module 16-3 may be a device for outputting a sound signal to the outside of the electronic device ED and include, for example, a speaker that is used for general purposes such as playing multimedia or playing a recording and a receiver that is used only for receiving a call. According to an embodiment, the receiver may be formed integrally with or separately from the speaker. A sound output pattern of the sound output module 16-3 may be integrated with the display module 14.

The camera module 17-1 may capture a still image and a moving image. According to an embodiment, the camera module 17-1 may include one or more lenses, an image sensor, or an image signal processor. The camera module 17-1 may further include an infrared camera capable of measuring presence/absence of a user, a position of a user, a gaze of a user, etc.

The light module 17-2 may provide light. The light module 17-2 may include a light-emitting diode or a xenon lamp. The light module 17-2 may operate in association with the camera module 17-1 or may operate independently.

The communication module 17-3 may support establishing a wired or wireless communication channel between the electronic device ED and the external electronic device OD and performing communication via the established communication channel. The communication module 17-3 may include any one of or both of a wireless communication module such as a cellular communication module, a short-range wireless communication module, or a global navigation satellite system (GNSS) communication module and a wired communication module such as a local area network (LAN) communication module or a power line communication module. The communication module 17-3 may communicate with the external electronic device OD via a short-range communication network such as Bluetooth, Wi-Fi direct, or infrared data association (IrDA) or a long-range communication network such as a cellular network, internet, or a computer network (for example, LAN or WAN). The various types of the communication module 17-3 described above may be implemented as one chip or may be implemented as separate chips.

The input module 13, the sensor module 16-1, the camera module 17-1, etc., may be used to control an operation of the display module 14 in association with the processor 11.

The processor 11 may output a command or data to the display module 14, the sound output module 16-3, the camera module 17-1, or the light module 17-2 on the basis of input data received from the input module 13. For example, the processor 11 may generate image data in correspondence to input data applied through a mouse, an active pen, or the like and output the image data to the display module 14, or may generate command data in correspondence to input data and output the command data to the camera module 17-1 or the light module 17-2. In case that input data is not received from the input module 13 for a certain amount of time, the processor 11 may change an operation mode of the electronic device ED to a low power mode or a sleep mode, thereby reducing power consumption of the electronic device ED.

The processor 11 may output a command or data to the display module 14, the sound output module 16-3, the camera module 17-1, or the light module 17-2 on the basis of sensing data received from the sensor module 16-1. For example, the processor 11 may compare authentication data applied by the fingerprint sensor 16-11 with authentication data stored in the memory 12, and then may execute an application according to a comparison result. The processor 11 may execute a command or output corresponding image data to the display module 14 on the basis of sensing data sensed by the input sensor 16-12 or the digitizer 16-13. In a case in which a temperature sensor is included in the sensor module 16-1, the processor 11 may receive temperature data about a measured temperature from the sensor module 16-1 and further perform luminance correction on image data, etc., on the basis of the temperature data.

The processor 11 may receive measurement data about presence/absence of a user, a position of a user, a gaze of a user, etc., from the camera module 17-1. The processor 11 may further perform luminance correction on image data, etc., on the basis of the measurement data. For example, the processor 11 may determine presence/absence of a user through an input from the camera module 17-1, and then the processor 11 may output image data of which luminance is corrected through the data conversion circuit 11-22 or the gamma correction circuit 11-23 to the display module 14.

Some of the above components may be connected to each other via a communication method between peripheral devices, for example, bus, general purpose input/output (GPIO), serial peripheral interface (SPI), mobile industry processor interface (MIPI), or ultra path interconnect (UPI) link, and may exchange a signal (for example, a command or data). The processor 11 may communicate with the display module 14 via a mutually agreed interface, and for example, may use one of the communication methods described above, and a communication method is not limited thereto.

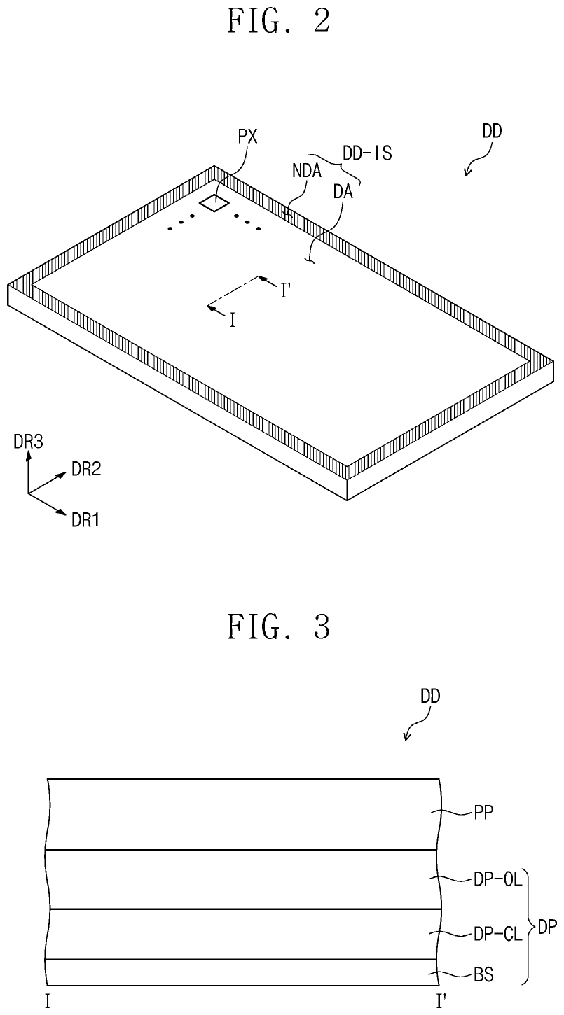

FIG. 2 is a schematic cross-sectional view illustrating a display device DD according to an embodiment. FIG. 2 illustrates the display device DD provided with a flat display surface DD-IS, but embodiments are not limited thereto. The display device DD may also include a curved display surface or a three-dimensional display surface. The three-dimensional display surface may also include display regions which respectively indicate different directions.

The display surface DD-IS may include a display region DA and a non-display region NDA. Pixels PX may be disposed in the display region DA, and the pixels PX are not disposed in the non-display region NDA. The non-display region NDA may be defined along a border of the display surface DD-IS. The non-display region NDA may surround the display region DA. However, embodiments are not limited thereto. In an embodiment, the non-display region NDA may be omitted and disposed only in one side of the display region DA.

A thickness direction of the display device DD may be parallel to a third direction DR3 which is the normal direction of the plane defined by a first direction DR1 and a second direction DR2. The directions indicated by the first to third directions DR1, DR2, and DR3 illustrated herein have a relative concept, and may thus be changed to other directions.

In the description, an upper surface (or front surface) and a lower surface (or rear surface) of each member constituting the display device DD may be defined based on the third direction DR3. In one member, among two surfaces facing each other in the third direction DR3, a surface relatively adjacent to the display surface DD-IS may be defined as a front surface (or upper surface), and a surface relatively spaced apart from the display surface DD-IS may be defined as a rear surface (or lower surface). In the description, an upper part and a lower part may be defined based on the third direction DR3. The upper part may be defined as a direction of getting closer to the display surface DD-IS, and the lower part may be defined as a direction of getting farther away from the display surface DD-IS.

FIG. 3 is a schematic cross-sectional view of a display device DD, according to an embodiment, taken along line I-I′ of FIG. 2.

Referring to FIG. 3, the display device DD may include a display panel DP and an upper member PP disposed on the display panel DP.

In the display device DD of an embodiment, the display panel DP may be a light-emitting display panel. For example, the display panel DP may be a quantum dot light-emitting display panel including a quantum dot light-emitting element. However, embodiments are not limited thereto.

The display panel DP may include a display element layer DP-OL. The display element layer DP-OL may include a light-emitting element. The display panel DP may include a base substrate BS, a circuit layer DP-CL disposed the base substrate BS, and the display element layer DP-OL disposed on the circuit layer DP-CL.

The base substrate BS may be a member which provides a base surface on which the circuit layer DP-CL and the display element layer DP-OL are disposed. The base substrate BS may be a glass substrate, a metal substrate, a plastic substrate, and the like. However, embodiments are not limited thereto, and the base substrate BS may be an inorganic layer, an organic layer, or a composite material layer. The base substrate BS may be a flexible substrate capable of being readily bent or folded.

In an embodiment, the circuit layer DP-CL may be disposed on the base substrate BS, and the circuit layer DP-CL may include transistors. The transistors may each include a control electrode, an input electrode, and an output electrode. For example, the circuit layer DP-CL may include a switching transistor or a driving transistor for driving a light-emitting element of the display element layer DP-OL.

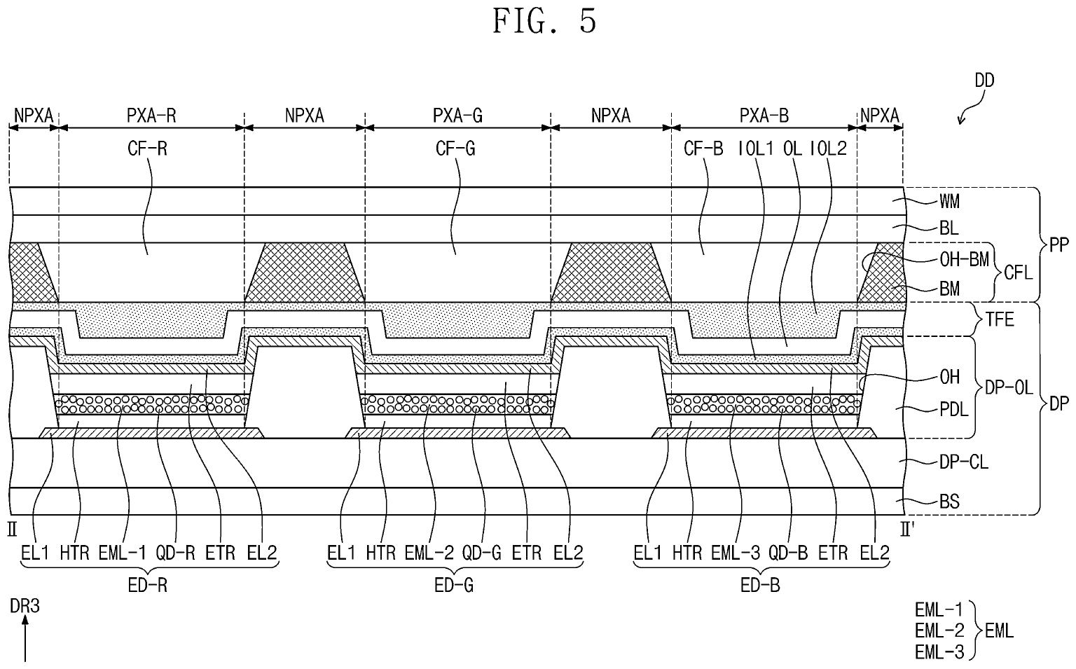

FIG. 4 is an enlarged schematic plan view illustrating a part of a display device according to an embodiment. FIG. 5 is a schematic cross-sectional view of a display device according to an embodiment. FIG. 5 illustrates a part taken along line II-II′ of FIG. 4.

Referring to FIG. 4, a display device DD of an embodiment may include a plane including three light-emitting regions PXA-R, PXA-G, and PXA-B and a non-light-emitting region NPXA adjacent thereto. In an embodiment, the three types of light-emitting regions PXA-R, PXA-G, and PXA-B illustrated in FIG. 4 may be repeatedly disposed in the entire display region DA (see FIG. 2).

The non-light-emitting region NPXA may be disposed around the first to third light-emitting regions PXA-R, PXA-G, and PXA-B. The non-light-emitting region NPXA defines boundaries between the first to third light-emitting regions PXA-R, PXA-G, and PXA-B. The non-light-emitting region NPXA may surround the first to third light-emitting regions PXA-R, PXA-G, and PXA-B. A structure, such as a pixel-defining film PDL (see FIG. 5), which prevents color-mixing between the first to third light-emitting regions PXA-R, PXA-G, and PXA-B may be disposed in the non-light-emitting region NPXA.

FIG. 4 illustrates that the first to third light-emitting regions PXA-R, PXA-G, and PXA-B have the same planar shape and have different planar areas, but embodiments are not limited thereto. At least two light-emitting regions among the first to third light-emitting regions PXA-R, PXA-G, and PXA-B may have the same area. Areas of the first to third light-emitting regions PXA-R, PXA-G, and PXA-B may be set according to colors of emitted light.

FIG. 4 illustrates that the first to third light-emitting regions PXA-R, PXA-G, and PXA-B each have a rectangular shape, but embodiments are not limited thereto. In plan view, the first to third light-emitting regions PXA-R, PXA-B, and PXA-G may each have another polygonal shape (including a substantially polygonal shape) such as a rhombic or pentagonal shape. In an embodiment, in plan view, the first to third light-emitting regions PXA-R, PXA-B, and PXA-G may each have a rectangular shape with rounded corners (a substantially rectangular shape).

FIG. 4 illustrates that the second light-emitting region PXA-G is disposed in a first row and the first light-emitting region PXA-R and the third light-emitting region PXA-B are disposed in a second row, but embodiments are not limited thereto. An arrangement of the first to third light-emitting regions PXA-R, PXA-G, and PXA-B may change variously. For example, the first to third light-emitting regions PXA-R, PXA-G, and PXA-B may be disposed in the same row.

FIG. 4 illustrates the display device DD of an embodiment in which the three light-emitting regions PXA-R, PXA-G, and PXA-B respectively emit blue light, green light, and red light. For example, the display device DD of an embodiment may include a red light-emitting region PXA-R, a green light-emitting region PXA-G, and a blue light-emitting region PXA-B, which are separated from each other. In the description, the red light-emitting region PXA-R, the green light-emitting region PXA-G, and the blue light-emitting region PXA-B may be respectively referred to as a first light-emitting region PXA-R, a second light-emitting region PXA-G, and a third light-emitting region PXA-B.

Referring to FIGS. 4 and 5, the first light-emitting region PXA-R, the second light-emitting region PXA-G, and the third light-emitting region PXA-B of the display device DD may respectively correspond to a first light-emitting element ED-R, a second light-emitting element ED-G, and a third light-emitting element ED-B. Multiple light-emitting elements ED-R, ED-G, and ED-B may emit light having wavelength ranges different from each other. In an embodiment, the display device DD may include the first light-emitting element ED-R which generates first light, the second light-emitting element ED-G which generates second light, and the third light-emitting element ED-B which generates third light. For example, the display device DD may include the first light-emitting element ED-R which generates red light, the second light-emitting element ED-G which generates green light, and the third light-emitting element ED-B which generates blue light. The first to third light-emitting elements ED-R, ED-G, and ED-B respectively include first to third quantum dots QD-R, QD-G, and QD-B, and may thus emit red light, green light, and blue light. However, embodiments are not limited thereto, and the first to third light-emitting elements ED-R, ED-G, and ED-B may emit light having the same wavelength range, or at least one thereamong may emit light having a wavelength range different from the others.

In the display device DD of an embodiment, areas of the light-emitting regions PXA-R, PXA-G, and PXA-B may be different from each other. For example, the light-emitting regions PXA-R, PXA-G, and PXA-B may have different areas according to the colors of light emitted from the light-emitting layers EML-1, EML-2, and EML-3 of the light-emitting elements ED-R, ED-G, and ED-B. For example, the areas may mean areas when viewed on a plane defined by the first direction DR1 and the second direction DR2. For example, in the display device DD of an embodiment, the green light-emitting region PXA-G corresponding to the second light-emitting element ED-G which emits green light may have the greatest area, and the blue light-emitting region PXA-B corresponding to the third light-emitting element ED-B which generates blue light may have the smallest area. However, embodiments are not limited thereto, and the light-emitting regions PXA-R, PXA-G, and PXA-B may emit light having another color, in addition to blue light, green light, and red light. In another example, the light-emitting regions PXA-R, PXA-G, and PXA-B may be provided to have the same area, or to have an area ratio different from that illustrated in FIG. 4.

Referring to FIG. 5, the display device DD of an embodiment may include a display panel DP including the plurality of light-emitting elements ED-R, ED-G, and ED-B, and an upper member PP disposed on the display panel DP.

The display panel DP may include a base substrate BS, a circuit layer DP-CL provided on the base substrate BS, and a display element layer DP-OL. The display element layer DP-OL may include pixel-defining films PDL, the light-emitting elements ED-R, ED-G and ED-B disposed between the pixel-defining films PDL or on the pixel-defining films PDL, and an encapsulation layer TFE disposed on the light-emitting elements ED-R, ED-G, and ED-B.

The display element layer DP-OL may include the pixel-defining films PDL. The light-emitting regions PXA-R, PXA-G, and PXA-B may be separated by the pixel-defining films PDL. Non-light-emitting regions NPXA may be regions, which are between the adjacent light-emitting regions PXA-R, PXA-G and PXA-B and correspond to the pixel-defining films PDL. In the description, the light-emitting regions PXA-R, PXA-G, and PXA-B may each correspond to a pixel. The pixel-defining films PDL may separate the light-emitting elements ED-R, ED-G, and ED-B. For example, the light-emitting layers EML-1, EML-2, and EML-3 of the light-emitting elements ED-R, ED-G, and ED-B may be respectively disposed in openings OH defined by the pixel-defining films PDL and be separated from each other.

The pixel-defining film PDL may be formed of a polymer resin. For example, the pixel-defining films PDL may be formed of a polyacrylate-based resin or a polyimide-based resin. For example, the pixel-defining film PDL may be formed by further including an inorganic material in addition to a polymer resin. For example, the pixel-defining film PDL may be formed of a light-absorbing material, or of a black pigment or black dye. The pixel-defining film PDL formed of a black pigment or black dye may constitute a black pixel-defining film. In case of forming the pixel-defining film PDL, carbon black, etc., may be used as a black pigment or black dye, but embodiments are not limited thereto.

The pixel-defining film PDL may be formed of an inorganic material. For example, the pixel-defining film PDL may be formed of silicon nitride (SiNx), silicon oxide (SiOx), silicon nitride (SiOxNy), and the like. The pixel-defining film PDL may define the light-emitting elements PXA-R, PXA-G, and PXA-B. The light-emitting regions PXA-R, PXA-G, and PXA-B, and the non-light-emitting region NPXA may be separated by the pixel-defining film PDL.

The display element layer DP-OL may include the light-emitting elements ED-R, ED-G, and ED-B disposed between the pixel-defining films PDL. The display device DD of an embodiment may include first to third light-emitting elements ED-R, ED-G, and ED-B, and the light-emitting elements ED-R, ED-G, and ED-B may respectively include first to third light-emitting layers EML-1, EML-2, and EML-3. The first to third light-emitting elements ED-R, ED-G, and ED-B according to an embodiment may include a first electrode EL1, a second electrode EL2 facing the first electrode EL1, and first to third light-emitting layers EML-1, EML-2, and EML-3 disposed between the first electrode EL1 and the second electrode EL2. The first to third light-emitting layers EML-1, EML-2, and EML-3 may include an inorganic light-emitting material. The first to third light-emitting layers EML-1, EML-2, and EML-3 may respectively include first to third quantum dots QD-R, QD-G, and QD-B. The first to third light-emitting elements ED-R, ED-G, and ED-B according to an embodiment may further include multiple functional layers disposed between the first electrode EL1 and the second electrode EL2. The plurality of functional layers may include a hole transport region HTR disposed between the first electrode EL1 and the light-emitting layer EML, and an electron transport region ETR disposed between the light-emitting layer EML and the second electrode EL2.

The encapsulation layer TFE may be disposed on the display element layer DP-OL. The encapsulation layer TFE may be disposed on the light-emitting elements ED-R, ED-G, and ED-B and protect the light-emitting elements ED-R, ED-G, and ED-B. The encapsulation layer TFE may have a multi-layered structure in which an inorganic layer/an organic layer are repeated. The encapsulation layer TFE may include a first inorganic layer IOL1, an organic layer OL, and a second inorganic layer IOL2 which are sequentially stacked.

The first and second inorganic layers IOL1 and IOL2 may protect the light-emitting elements ED-R, ED-G, and ED-B against external moisture. The first and second inorganic layers IOL1 and IOL2 may protect the display element layer DP-OL against moisture and oxygen. The first and second inorganic layers IOL1 and IOL2 may each include silicon nitride, silicon oxynitride, silicon oxide, titanium oxide, aluminum oxide, or the like. However, materials included in the first and second inorganic layers IOL1 and IOL2 are not limited thereto.

The organic layer OL may protect the display element layer DP-OL against foreign substances such as dust particles. For example, the organic layer OL may prevent a dent defect in the light-emitting elements ED-R, ED-G, and ED-B due to foreign substances introduced during a process of manufacturing the display element layer DP-OL.

The organic layer OL may include a resin material. The organic layer OL may include, as the resin material, an acrylate-based compound, an epoxy-based compound, and the like. The resin material may include a photopolymerizable organic material. For example, the resin material may include any one among epoxy, polyimide, polyethylene terephthalate, polycarbonate, polyethylene, and polyacrylate. However, a resin material included in the organic layer OL is not limited thereto. The organic layer OL may include the resin material, and thus the encapsulation layer TFE including the organic layer OL may protect the display element layer DP-OL against foreign substances such as dust particles.

The organic layer OL may include an acidic material. Accordingly, the organic layer OL may contain an acidic gas. The organic layer OL may contain protons which are hydrogen ion (H+) gases. The protons contained in the organic layer OL may be generated from an acidic material. The protons contained in the organic layer OL may be provided to the light-emitting elements ED-R, ED-G, and ED-B. The acidic material may be a weak organic acidic material. The acidic material may have a pKa of about 3.0 to about 3.5. For example, the acidic material may have a pKa of about 3.0 to about 3.3. The acidic material may have a molecular weight of about 180 to about 200. For example, the acidic material may have a molecular weight of about 190 to about 195. The acidic material included in the organic layer OL of an embodiment may include citric acid.

The organic layer OL may include an acidic material, and further include an acid polymer material. The acid polymer material may include polyacrylic acid (PAA).

The display device DD of an embodiment may include an upper member PP. The upper member PP may be disposed on the display panel DP. The upper member PP may include an optical layer CFL, an optical structure layer BL disposed on the optical layer CFL, and a window WM disposed on the optical structure layer BL.

The window WM may include an optically transparent insulating material. For example, the window WM may include glass, sapphire, plastic, or the like. The window WM may have a single- or multi-layered structure. The window WM may further include functional layers such as an anti-fingerprint layer disposed on an optically transparent substrate. The window WM may not include the acidic material of the above-described encapsulation layer TFE and a resin material of the encapsulation layer TFE. A material included in the window WM may be different from each of the resin material and the acidic material of the encapsulation layer TFE.

The optical structure layer BL may block external light provided from the outside of the display device DD to the display panel DP. The optical structure layer BL may be a reflection reduction layer which reduces reflectance for external light. For example, the optical structure layer BL may include a polarizing film including a retarder and/or a polarizer, and multi-layered reflective layers which cause destructive interference of reflected light. In another embodiment, the optical structure layer BL may be omitted.

The optical layer CFL may include color filters CF-R, CF-G, and CF-B, and light blocking parts BM in which light blocking openings OH-BM are defined.

First to third color filters CF-R, CF-G, and CF-B may each include a polymer photosensitive resin and a colorant. The first to third color filters CF-R, CF-G, and CF-B may be disposed to respectively correspond to first to third light-emitting regions PXA-R, PXA-G, and PXA-B. The first to third color filters CF-R, CF-G, and CF-B may be respectively disposed in the light blocking openings OH-BM defined in the light blocking parts BM, and may be separated from each other. In the description, the first color filter CF-R may be referred to as “a first optical part”, the second color filter CF-G may be referred to as “a second optical part”, and the third color filter CF-B may be referred to as “a third optical part”.

The optical layer CFL may include the first to third color filters CF-R, CF-G, and CF-B respectively corresponding to first to third light-emitting regions PXA-R, PXA-G, and PXA-B. The optical layer CFL may include the first color filter CF-R which transmits first light, the second color filter CF-G which transmits second light, and the third color filter CF-B which transmits third light. The first color filter CF-R may transmit red light, the second color filter CF-G may transmit green light, and the third color filter CF-B may transmit blue light. In an embodiment, the first color filter CF-R may be a red filter, the second color filter CF-G may be a green filter, and the third color filter CF-B may be a blue filter. The first color filter CF-R may include a red pigment or a red dye, the second color filter CF-G may include a green pigment or a green dye, and the third color filter CF-B may include a blue pigment or a blue dye. In another example, the first color filter CF-R and the second color filter CF-G may be yellow filters. The first color filter CF-R and the second color filter CF-G may be integrally provided without being separated from each other. In another example, the third color filter CF-B may not include a pigment or a dye. The third color filter CF-B may include a polymer photosensitive resin and may not include a pigment or a dye. The third color filter CF-B may be transparent. The third color filter CF-B may be formed of a transparent photosensitive resin.

The first to third color filters CF-R, CF-G, and CF-B may each be formed through a coating step, an exposure step, a development step, and a heat-drying step. In an embodiment, the step of forming each of the first to third color filters CF-R, CF-G, and CF-B may include steps of: providing first to third resin compositions including a polymer photosensitive resin and a pigment or dye; applying the first to third resin compositions so as to correspond to the light-emitting regions PXA-R, PXA-G, and PXA-B; and exposing and developing the applied resin composition and then heat-drying the composition. For example, the heat-drying step may be performed at about 90° C. to about 300° C. Accordingly, the step of forming each of the first to third color filters CF-R, CF-G, and CF-B may include a high temperature process. However, the step of forming each of the first to third color filters CF-R, CF-G, and CF-B is not limited thereto, and the first to third color filters CF-R, CF-G, and CF-B may each be formed through a low-temperature process.

The optical layer CFL may include the light blocking part BM defining boundaries between the adjacent color filters CF-R, CF-G, and CF-B. The light blocking part BM may be disposed to correspond to the non-light-emitting region NPXA disposed between the light-emitting regions PXA-R, PXA-G, and PXA-B. The light blocking part BM may function to prevent light leakage and color-mixing. The light blocking part BM may be formed by a blue filter, or formed of an organic light-blocking material or an inorganic light-blocking material which contains a black pigment or a black dye. The light blocking part BM may be a black matrix.

For example, the optical layer CFL may further include a buffer layer. For example, the buffer layer may be a protective layer which protects the color filters CF-R, CF-G, and CF-B. The buffer layer may be an inorganic layer including at least one inorganic material selected from silicon nitride, silicon oxide, and silicon oxynitride. The buffer layer may be composed of a single layer or multiple layers.

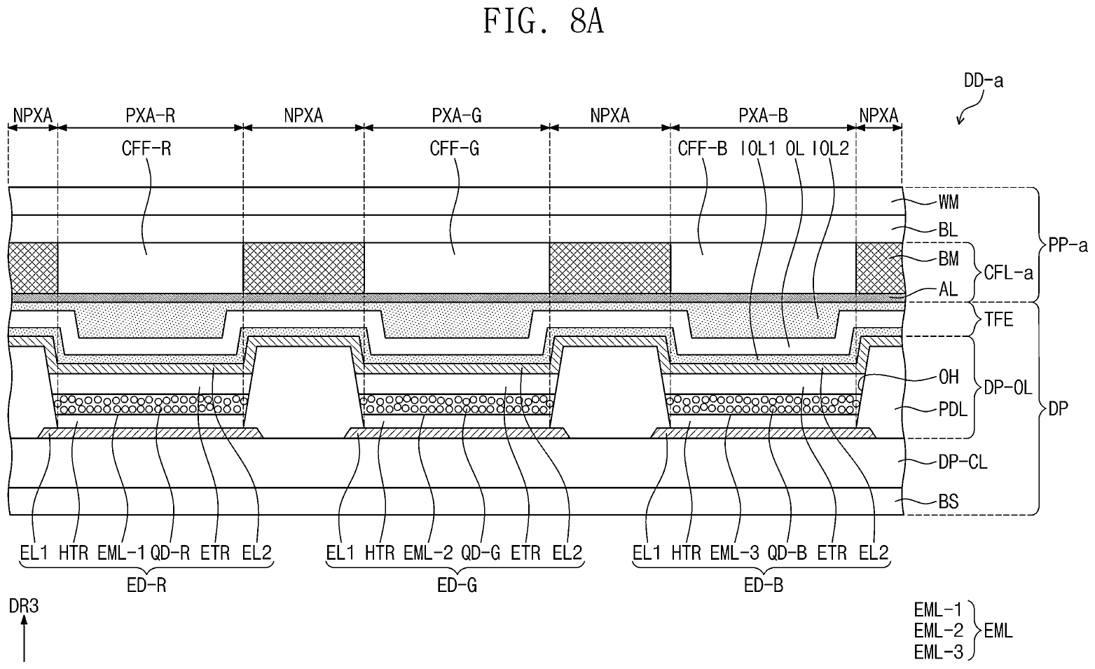

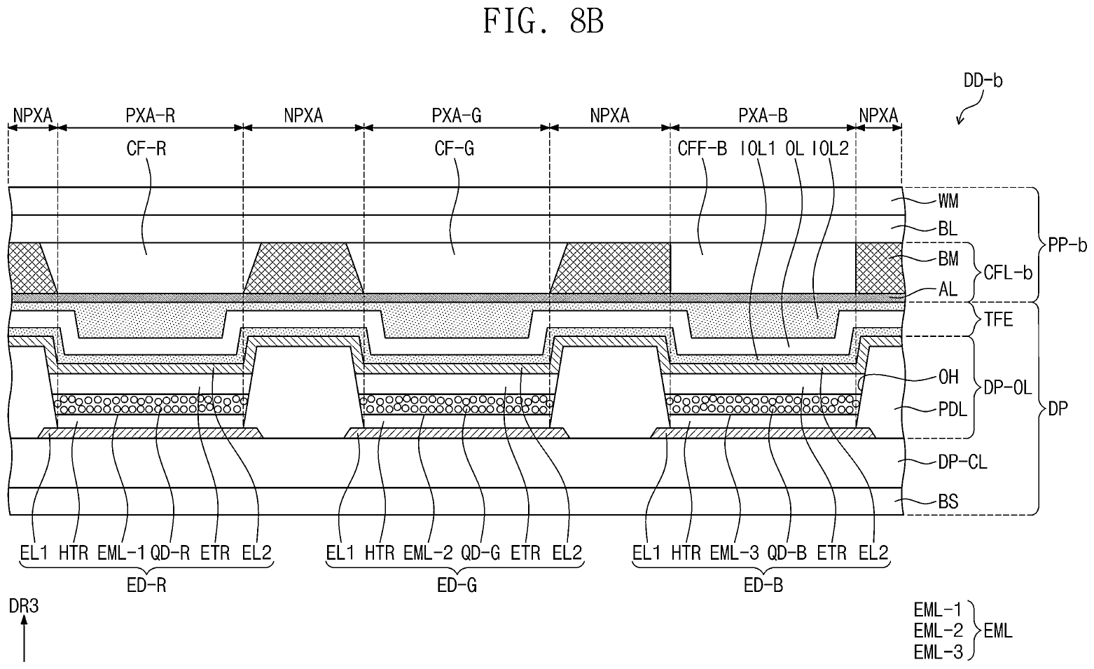

FIG. 6 is a schematic cross-sectional view of a light-emitting element included in a display device according to an embodiment. FIG. 7 is a schematic cross-sectional view of a quantum dot included in a display device according to an embodiment. FIG. 6 illustrates any one light-emitting element ED among the light-emitting elements ED-R, ED-G, and ED-B of FIG. 5 described above, and FIG. 7 illustrates any one quantum dot QD among the quantum dots QD-R, QD-G, and QD-B of FIG. 5 described above. The following description of the light-emitting element ED may be applied to each of the light-emitting elements ED-R, ED-G, and ED-B of FIG. 5, and the following description of the quantum dot QD may be applied to each of the quantum dots QD-R, QD-G, and QD-B of FIG. 5.

Referring to FIG. 6, the light-emitting element ED according to an embodiment may include a first electrode EL1, and a second electrode EL2 facing the first electrode EL1, and may also include a hole transport region HTR, a light-emitting layer EML, and an electron transport region ETR, which are disposed between the first electrode EL1 and the second electrode EL2.

The first electrode EL1 may have conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode EL1 may include: at least one selected from among Ag, Mg, Cu, Al, Pt, Pd, Au, Ni, Nd, Ir, Cr, Li, Ca, LiF, Mo, Ti, W, In, Sn, or Zn; a compound of two or more materials selected from thereamong; a mixture of two or more materials selected from thereamong; or an oxide thereof.

In case that the first electrode EL1 is the transmissive electrode, the first electrode EL1 may include a transparent metal oxide, for example, indium tin oxide (ITO), indium zinc oxide (IZO), zinc oxide (ZnO), indium tin zinc oxide (ITZO), and the like. In case that the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, W, or a compound or mixture thereof (for example, a mixture of Ag and Mg). In another example, the first electrode EL1 may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), and the like. For example, the first electrode EL1 may have a three-layered structure of ITO/Ag/ITO, but embodiments are not limited thereto. The first electrode EL1 may have conductivity. The first electrode EL1 may be formed of a metal material, metal alloy, or conductive compound. The first electrode EL1 may be an anode or a cathode. However embodiments are not limited thereto. For example, the first electrode EL1 may be a pixel electrode. The first electrode EL1 may be a transmissive electrode, a transflective electrode, or a reflective electrode. The first electrode EL1 may include: at least one selected from among Ag, Mg, Cu, Al, Pt, Pd, Au, Ni, Nd, Ir, Cr, Li, Ca, LiF, Mo, Ti, W, In, Sn, or Zn; a compound of two or more materials selected from thereamong; a mixture of two or more materials selected from thereamong; or an oxide thereof.

The hole transport region HTR may be provided on the first electrode EL1. The hole transport region HTR may include a hole injection layer HIL and a hole transport layer HTL. For example, the hole transport region HTR may further include an electron blocking layer. In another example, the hole transport region HTR may be a single layer formed of a single material or have a single-layered structure formed of multiple different materials.

The hole transport region HTR may include a typical hole injection material and/or a typical hole transport material. For example, the hole transport region HTR may include a phthalocyanine compound, such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl) borate], dipyrazino[2,3-f: 2′,3′-h]quinoxaline-2,3,6,7,10,11-hexacarbonitrile (HATCN), and the like.

For example, the hole transport region HTR may also include a carbazole-based derivative, such as N-phenylcarbazole and polyvinylcarbazole, a fluorene-based derivative, a triphenylamine-based derivative, such as N,N′-bis(3-methylphenyl)-N,N′-diphenyl-[1,1-biphenyl]-4,4′-diamine (TPD) and 4,4′,4″-tris(N-carbazolyl)triphenylamine (TCTA), N,N′-di(naphthalene-1-yl)-N,N′-diphenyl-benzidine (NPD), 4,4′-Cyclohexylidene bis[N,N-bis(4-methylphenyl)benzenamine](TAPC), 4,4′-Bis[N,N′-(3-tolyl)amino]-3,3′-dimethylbiphenyl (HMTPD), 1,3-Bis(N-carbazolyl)benzene (mCP), and the like.

The hole transport region HTR may have a thickness of about 5 nm to about 1,500 nm, for example, about 10 nm to about 500 nm. In case that the thickness of the hole transport region HTR satisfies the above-described range, a hole transport characteristic may be satisfactorily achieved without a substantial increase in a driving voltage.

The light-emitting layer EML may be disposed (or provided) on the hole transport region HTR. The light-emitting layer EML may include a quantum dot QD. The quantum dot QD may be provided in plurality and stacked to form a layer. FIG. 6 illustrates that the quantum dots QD each having a circular cross-section are arranged and to roughly form two layers, but embodiments are not limited thereto. For example, an arrangement of the quantum dots QD may vary according to a thickness of the light-emitting layer EML, shapes of the quantum dots QD included in the light-emitting layer EML, an average diameter of the quantum dots QD, and the like. In the light-emitting layer EML, the quantum dots QD may be aligned adjacent to each other to constitute one layer, or may be aligned so as to form multiple layers, such as two or three layers.

Referring to FIGS. 6 and 7, the quantum dots QD may each include a core CR and a shell SL surrounding the core. Accordingly, the quantum dot QD may have a core/shell structure.

The quantum dot QD means a crystal of a semiconductor compound. The quantum dot QD may emit light having various light-emission wavelengths according to a size of a crystal. The quantum dot QD may also emit light having various light-emission wavelengths by adjusting an element ratio in the included compound.

For example, the quantum dot QD may have a diameter of about 1 nm to about 10 nm. The quantum dots QD may be synthesized through a wet chemical process, a metal organic chemical vapor deposition process, a molecular beam epitaxy process, or processes similar thereto. The wet chemical process among manufacturing processes of the quantum dots QD may be a method of growing quantum dot particle crystals after mixing an organic solvent and a precursor material. In case that the quantum dot particle crystals grow, the organic solvent may naturally function as a dispersing agent coordinated on the surfaces of the quantum dot crystals, and thus growth of the particle crystal may be controlled. Accordingly, the wet chemical process is performed easier than a vapor deposition method such as a metal organic chemical vapor deposition (MOCVD) or a molecular beam epitaxy (MBE), thereby making it possible to control the growth of the quantum dot particles through a low-cost process.

The core CR of the quantum dot QD may be selected from among a group II-VI compound, a group III-V compound, a group III-VI compound, a group I-III-VI compound, a group IV-VI compound, a group IV element, a group IV compound, and combinations thereof. In the description, “the group” means a group of the IUPAC periodic table.

The group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. For example, the group II-VI semiconductor compound may further include a group I metal and/or a group IV element. The group I-II-VI compound may be selected from among CuSnS and CuZnS, and the group II-IV-VI compound may be selected from ZnSnS and the like. The group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The group III-VI compound may include a binary compound such as In₂S₃, In₂Se₃, a ternary compound such as InGaS₃, InGaSe₃, or any combination thereof.

The I-III-VI group compound may be selected from: a ternary compound selected from the group consisting of AgInS, AgInS₂, CuInS, CuInS₂, AgGaS₂, CuGaS₂, CuGaO₂, AgGaO₂, AgAlO₂, and a mixture thereof; or a quaternary compound such as AgInGaS₂, and CuInGaS₂.

The group III-V compound may be selected from the group consisting of: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AIPSb, InGaP, InAlP, InNP, InNAs, InNSb, InPAs, InPSb, and a mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. For example, the group III-V compound may further include a group II metal. For example, InZnP, etc., may be selected as the group III-II-V compound.

The group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof.

For example, the group II-IV-V semiconductor compound may be a ternary compound selected from the group consisting of ZnSnP, ZnSnP₂, ZnSnAs₂, ZnGeP₂, ZnGeAs₂, CdSnP₂, and CdGeP₂ and a mixture thereof.

The group IV element may be selected from the group consisting of Si, Ge, and a mixture thereof. The group IV compound may be a binary compound selected from the group consisting of SiC, SiGe, and a mixture thereof.

Elements, included in a multi-element compound, such as a binary compound, a ternary compound, and a quaternary compound, may each be present in a particle at a uniform concentration or a non-uniform concentration. For example, Chemical Formula representing quantum dots means a type of elements included in a quantum dot compound, and an element ratio in the compound may vary. For example, AgInGaS₂ may mean AgInxGa₁₋ₓS₂ (x is a real number between 0 and 1).

For example, the binary compound, the ternary compound, or the quaternary compound may be present in particles with a uniform concentration, or may be present in the same particles in a different state in which the concentrations thereof are partially distributed. For example, the quantum dot may have a core/shell structure in which one quantum dot surrounds another quantum dot. The core/shell structure may have a concentration gradient in which the concentration of an element present in the shell decreases toward the core.

The shell SL of the quantum dot QD may function as a protective layer for maintaining semiconductor properties by preventing chemical modification of the core CR and/or a charging layer for imparting electrophoretic properties to the quantum dot QD. The shell SL may have a single-layered structure or a multi-layered structure. An example of the shell SL of the quantum dot QD may include a metal oxide or a non-metal oxide, a semiconductor compound, or combinations thereof.

For instance, an example of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound such as MgAl₂O₄, CoFe₂O₄, NiFe₂O₄, CoMn₂O₄, but embodiments are not limited thereto.

An example of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot QD may have, in a light-emission wavelength spectrum, a full width of half maximum (FWHM) of about 45 nm or less, preferably about 40 nm or less, and more preferably about 30 nm or less, and in this range, a color purity or color gamut may be improved. For example, light emitted through the quantum dot QD may be emitted in all directions, and thus a wide viewing angle may be improved.

For example, a shape of the quantum dot QD may be a shape generally used in the art and not limited. However, for example, the spherical shape, pyramidal shape, multi-arm shape of the quantum dot may be used, or cubic nanoparticle, nanotube, nanowire, nanofiber, nanoplate-shaped particle, and the like may be used for the quantum dot.

An energy band gap of the quantum dot QD may be controlled by adjusting a size of the quantum dot or an element ratio in the included compound, and thus light having various wavelengths may be obtained from the light-emitting layer EML including the quantum dot QD. Therefore, the above-described quantum dots (forming quantum dots having different sizes or quantum dots in which an element ratio in the quantum dot compound varies) are used, and thus a light-emitting element which emits light having various wavelengths may be achieved. For example, the adjustment of the sizes of the quantum dots or an element ratio in the compounds may be selected such that red light, green light, and blue light is emitted. For example, in the quantum dots QD having the same core CR, the particle size of the quantum dot QD which emits blue light may be smaller than the particle size of the quantum dot QD which emits green light. However, embodiments are not limited thereto, and the particle sizes of the quantum dots QD, although having the same core CR, may be adjusted according to a forming material of the shell SL, a thickness of the shell SL, and the like. For example, in case that the quantum dots QD have various light-emission colors such as blue, red, and green, the quantum dots QD having different light-emission colors may respectively have different materials of the core CR.

In the light-emitting element ED of an embodiment, the electron transport region ETR may be provided on the light-emitting layer EML. The electron transport region ETR may include an electron transport layer ETL and an electron injection layer EIL. For example, the electron transport region ETR may be a single layer formed of a single material, or a single layer formed of multiple different materials. For example, the electron transport region ETR may have a single-layered structure of an electron injection layer or an electron transport layer, or may have a single-layered structure formed of an electron injection material and an electron transport material. For example, the electron transport region ETR may have a thickness of about 20 nm to about 150 nm.

The electron transport region ETR may include a metal oxide. The metal oxide may include at least one among SnO, SnO₂, CuGaO₂, Ga₂O₃, Cu₂O, SrCu₂O₂, SrTiO₃, CuAlO₂, Ta₂O₅, NiO, BaSnO₃, MoO₃, and TiO₂, or may be represented by the following Chemical Formula M-1. For example, the electron transport region ETR may include ZnO and/or ZnMgO.

Zn_{q}Me(_{1-q})O [Chemical Formula M-1]

In Chemical Formula M-1, q may be 0 to about 0.5. Me may be Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

The electron transport region ETR may include a typical electron injection material and/or a typical electron transport material. For example, the electron transport region ETR may include an anthracene-based compound, Alq3 (Tris(8-hydroxyquinolinato)aluminum), 1,3,5-tri[(3-pyridyl)-phen-3-yl]benzene, 2,4,6-tris(3′-(pyridin-3-yl) biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, TPBi (1,3,5-Tri (1-phenyl-1H-benzo[d]imidazol-2-yl)phenyl), or a mixture thereof. In another example, the electron transport region ETR may include a halide metal such as LiF, NaCl, CsF, RbCl, RbI, a lanthanide metal such as Yb, a metal oxide such as Li₂O, BaO, lithium quinolate (LiQ), or the like.

A second electrode EL2 may be a common electrode. The second electrode EL2 may be a cathode or an anode, but embodiments are not limited thereto. For example, in case that the first electrode EL1 is an anode, the second electrode EL2 may be a cathode, and in case that the first electrode EL1 is a cathode, the second electrode EL2 may be an anode.

The second electrode EL2 may be a transmissive electrode, a transflective electrode, or a reflective electrode. In case that the second electrode EL2 is the transmissive electrode, the second electrode EL2 may include a transparent metal oxide, for example, indium tin oxide (ITO), indium zinc oxide (IZO), zinc oxide (ZnO), indium tin zinc oxide (ITZO), and the like.

In case that the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or a mixture thereof (for example, AgMg, AgYb, or MgYb). In another example, the second electrode EL2 may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), and the like. For example, the second electrode EL2 may include the above-described metal materials, a combination of two or more metal materials selected from thereamong, oxides of the above-described metal materials, or the like.

The display device according to an embodiment may include an encapsulation layer, and may include an acidic material in an organic layer in the encapsulation layer. Accordingly, the display device according to an embodiment may exhibit the excellent display efficiency. For example, in case that an electron transport region of an embodiment includes a metal oxide, a defect such as formation of an oxygen vacancy may occur on a surface of the metal oxide. In case that a trap state occurs due to the defect, charges are trapped and quenched, and thus luminous efficiency and lifespan of elements may be lowered. However, the display device according to an embodiment may include the acidic material in the organic layer disposed on the electron transport region, thereby blocking the oxygen vacancy. For example, the display device according to an embodiment may supply protons generated from the acidic material in the organic layer to the electron transport region, and thus the defect on a surface of the metal oxide may be removed. Accordingly, the electrons may be readily supplied from the electron transport region to the light emitting layer, and thus the display panel according to an embodiment may exhibit the excellent light emission efficiency. Therefore, the display device including the organic layer according to an embodiment may exhibit the excellent display efficiency.

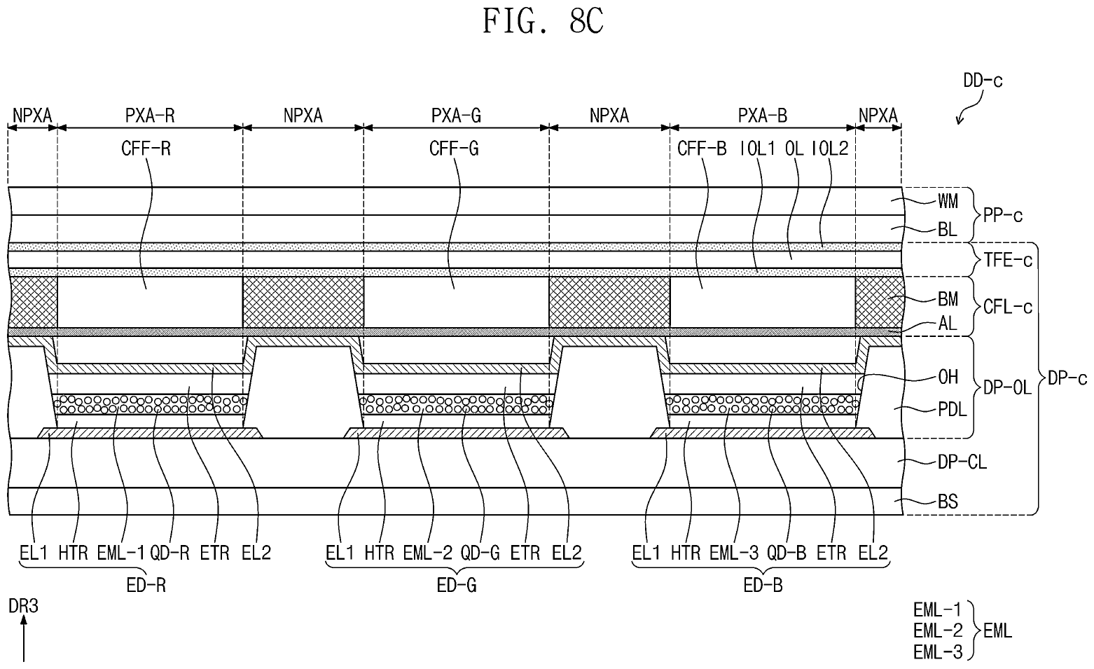

FIGS. 8A to 8C are schematic cross-sectional views of display devices DD-a, DD-b, and DD-c according to other embodiments. FIGS. 8A to 8C each illustrate a part taken along line II-II′ of FIG. 4, and respectively illustrate the display devices DD-a, DD-b, and DD-c of other embodiments different from that of the display device DD illustrated in FIG. 5. Hereinafter, with regard to the descriptions of FIGS. 8A to 8C, the contents duplicated with those described with the references to FIGS. 1 to 7 will not be explained again and the following description will be focused on the differences.

Referring to FIG. 8A, the display device DD-a of an embodiment may include a display panel DP and an upper member PP-a disposed on the display panel DP. The upper member PP-a may include an optical layer CFL-a disposed on the display panel DP.

The optical layer CFL-a may include color films CFF-R, CFF-G, and CFF-B, and an adhesive layer AL disposed between the color films CFF-R, CFF-G, and CFF-B and an encapsulation layer TFE. The optical layer CFL-a may not include the color filters CF-R, CF-G, and CF-B (see FIG. 5), and include the color films CFF-R, CFF-G, and CFF-B. The optical layer CFL-a may include a light blocking part BM disposed between the color films CFF-R, CFF-G, and CFF-B. However, embodiments are not limited thereto, and the light blocking part BM may be omitted from the optical layer CFL-a.

First to third color films CFF-R, CFF-G, and CFF-B may each include a color film. The first to third color films CFF-R, CFF-G, and CFF-B may each include polyvinyl chloride or cellophane. The first to third color films CFF-R, CFF-G, and CFF-B may each be a colored single-layered film including polyvinyl chloride or cellophane. The first to third color films CFF-R, CFF-G, and CFF-B may be disposed to respectively correspond to first to third light-emitting regions PXA-R, PXA-G, and PXA-B. In the description, the first color film CFF-R may be referred to as “a first optical part”, the second color film CFF-G may be referred to as “a second optical part”, and the third color film CFF-B may be referred to as “a third optical part”.

The optical layer CFL-a may include the first to third color films CFF-R, CFF-G, and CFF-B respectively corresponding to first to third light-emitting regions PXA-R, PXA-G, and PXA-B. The optical layer CFL-a may include the first color film CFF-R which transmits first light, the second color film CFF-G which transmits second light, and the third color film CFF-B which transmits third light. The first color film CFF-R may transmit red light, the second color film CFF-G may transmit green light, and the third color film CFF-B may transmit blue light. In an embodiment, the first color film CFF-R may be a red film, the second color film CFF-G may be a green film, and the third color film CFF-B may be a blue film.

A step of forming each of the first to third color films CFF-R, CFF-G, and CFF-B may include a laser transferring step. The step of forming the first to third color films CFF-R, CFF-G, and CFF-B may include a step of transferring laser onto the red film, the green film, and the blue film so as to respectively correspond to the light-emitting regions PXA-R, PXA-G, and PXA-B. In another example, the step of forming each of the first to third color films CFF-R, CFF-G, and CFF-B may include a stamping process or a pressing process. In another embodiment, the step of forming each of the first to third color films CFF-R, CFF-G, and CFF-B may include a nozzle printing process. Accordingly, the step of forming each of the first to third color films CFF-R, CFF-G, and CFF-B may include a low temperature process. The step of forming each of the first to third color films CFF-R, CFF-G, and CFF-B may be performed through the low temperature process, and thus it is possible to increase the process efficiency of manufacturing the display device DD-a of an embodiment, and to prevent decomposition, etc., of an acidic material included in the encapsulation layer TFE of an embodiment.

The color films CFF-R, CFF-G, and CFF-B may be attached to the encapsulation layer TFE via the adhesive layer AL. The adhesive layer AL may be a pressure sensitive adhesive film (PSA), an optically clear adhesive film (OCA), or an optically clear resin (OCR). The adhesive layer AL may include a photocurable adhesive material or a thermosetting adhesive material, and materials thereof are not limited. The adhesive layer AL may be omitted.

Referring to FIG. 8B, the display device DD-b of an embodiment may include a display panel DP and an upper member PP-b disposed on the display panel DP. The upper member PP-b may include an optical layer CFL-b disposed on the display panel DP.

The optical layer CFL-b may include a color filter corresponding to a partial region of the light-emitting regions PXA-R, PXA-G, and PXA-B, and a color film corresponding to a rest region among the light-emitting regions PXA-R, PXA-G, and PXA-B. FIG. 8B illustrates a structure in which the optical layer CFL-b includes first and second color filters CF-R and CF-G respectively corresponding to the first and second light-emitting regions PXA-R and PXA-G, and a third color film CFF-B corresponding to the third light-emitting region PXA-B. For example, the optical layer CFL of another embodiment may include a first color filter CF-R corresponding to the first light-emitting region PXA-R, and second and third color films CFF-G and CFF-B respectively corresponding to the second and third light-emitting regions PXA-G and PXA-B. However, embodiments are not limited thereto, and the optical layer CFL may include a component corresponding to the above-described color filter or color film according to the light-emitting regions PXA-R, PXA-G, and PXA-B.

Referring to FIG. 8C, the display device DD-c of an embodiment may include a display panel DP-c.

The display panel DP-c of an embodiment may include an optical layer CFL-c. Unlike what is illustrated in FIGS. 5, and 8A, the optical layer CFL-c of FIG. 8C may not be included in the upper member PP-c and may be included in the display panel DP-c. The optical layer CFL-c may be disposed on the display element layer DP-OL. The optical layer CFL-c may be disposed between the display element layer DP-OL and an encapsulation layer TFE-c. In the display panel DP-c according to an embodiment, the encapsulation layer TFE-c may be disposed on the optical layer CFL-c although including an acidic material, and thus the process efficiency during manufacture of the display device DD-c of an embodiment may be increased.

A display panel according to an embodiment may include an encapsulation layer including an acidic material, and thus the emission efficiency may be improved. A display device according to one embodiment may include the display panel of an embodiment, and thus the reliability may be improved.

Although the embodiments have been described, it is understood that the disclosure should not be limited to these embodiments but various changes and modifications can be made by one ordinary skilled in the art in the spirit and scope of the disclosure as hereinafter claimed. Therefore, the technical scope of the disclosure is not limited to the contents described in the detailed description of the specification, but should be determined by the claims.

What is claimed is:

1. A display device comprising:
a display panel; and
a window disposed on the display panel, wherein
the display panel comprises:
a base layer,
a circuit layer disposed on the base layer,
a display element layer disposed on the circuit layer and comprising a light-emitting element, and
an encapsulation layer disposed on the display element layer,
the encapsulation layer comprises:
a first inorganic layer disposed on the display element layer,
an organic layer disposed on the first inorganic layer, and
a second inorganic layer disposed on the organic layer, and
the organic layer comprises a resin material and an acidic material and provides protons to the light-emitting element.

2. The display device of claim 1, wherein the protons are generated from the acidic material.

3. The display device of claim 1, wherein a material comprised in the window is different from each of the resin material and the acidic material.

4. The display device of claim 1, wherein the acidic material has a pKₐ of about 3.0 to about 3.5.

5. The display device of claim 1, wherein the acidic material has a molecular weight of about 180 to about 200.

6. The display device of claim 1, wherein the acidic material comprises citric acid.

7. The display device of claim 1, wherein the resin material comprises an acrylate-based compound or an epoxy-based compound.

8. The display device of claim 1, wherein the organic layer further comprises an acid polymer material.

9. The display device of claim 8, wherein the acid polymer material comprises polyacrylic acid (PAA).

10. The display device of claim 1, wherein
the light-emitting element comprises:
a first electrode;
a hole transport region disposed on the first electrode;
a light-emitting layer disposed on the hole transport region;
an electron transport region disposed on the light-emitting layer; and
a second electrode disposed on the electron transport region, and
the light-emitting layer comprises quantum dots.

11. The display device of claim 10, wherein the electron transport region comprises a metal oxide.

12. The display device of claim 1, further comprising:
an optical layer disposed below the window.

13. The display device of claim 12, wherein
the light-emitting element comprises:
a first light-emitting element overlapping a first light-emitting region,
a second light-emitting element overlapping a second light-emitting region, and
a third light-emitting element overlapping a third light-emitting region, and
the optical layer comprises:
a first optical part overlapping the first light-emitting region,
a second optical part overlapping the second light-emitting region, and
a third optical part overlapping the third light-emitting region.

14. The display device of claim 13, wherein the first optical part, the second optical part, and the third optical part each comprise a polymer photosensitive resin.

15. The display device of claim 14, wherein
the first optical part comprises a red colorant,
the second optical part comprises a green colorant, and
the third optical part comprises a blue colorant.

16. The display device of claim 13, wherein the first optical part, the second optical part, and the third optical part each comprise a color film.

17. The display device of claim 16, wherein the optical layer further comprises an adhesive layer disposed below the first optical part, the second optical part, and the third optical part.

18. The display device of claim 13, wherein
at least one among the first optical part, the second optical part, and the third optical part comprises a polymeric photosensitive resin, and
remains among the first optical part, the second optical part, and the third optical part comprises a color film.

19. A display panel comprising:
a base layer;
a circuit layer disposed on the base layer;
a display element layer disposed on the circuit layer and comprising a light-emitting element; and
an encapsulation layer disposed on the display element layer,
wherein the encapsulation layer comprises:
a first inorganic layer disposed on the display element layer,
an organic layer disposed on the first inorganic layer and comprising citric acid, and
a second inorganic layer disposed on the organic layer.

20. An electronic device which provides an image,
the electronic device comprising a display device a power supply module for supplying power to the display device,
the display device comprising:
a display panel; and
a window disposed on the display panel, wherein
the display panel comprises:
a base layer,
a circuit layer disposed on the base layer,
a display element layer disposed on the circuit layer and comprising a light-emitting element, and
an encapsulation layer disposed on the display element layer,
the encapsulation layer comprises:
a first inorganic layer disposed on the display element layer,
an organic layer disposed on the first inorganic layer, and
a second inorganic layer disposed on the organic layer, and
the organic layer comprises a resin material and an acidic material and provides protons to the light-emitting element.
